(19) United States
(12) Patent Application Publication
(10) Pub. No.: US 2010/0288336 A1
(43) Pub. Date: Nov. 18, 2010

(54) Solar Cell Array

(75) Inventors: Takahiro Kitano, Higashiomi-shi (JP); Toshiaki Ohno, Higashiomi-shi (JP); Akihito Ito, Ise-city (JP)

Correspondence Address: Hogan Lovells US LLP, 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/681,764

(22) PCT Filed: Oct. 3, 2008
(86) PCT No.: PCT/JP2008/068032

§ 371 Date: Jun. 14, 2010

(30) Foreign Application Priority Data
Oct. 3, 2007 (JP) 2007-259666

(51) Int. Cl. H01L 31/048

(52) U.S. Cl. 136/251

(57) ABSTRACT

Provided is a solar cell array having excellent power generation efficiency by being capable of efficiently cooling solar cell panels with a simple structure. The solar cell array according to the present invention includes a first solar cell panel and a second solar cell panel, and an installation member configured to install the first and second solar cell panels, the installation member being disposed with a space on back surface side of the installation member when installed, and holds the first and second solar cell panels with a gap between a first edge along one side of the first solar cell panel and a second edge along one side of the second solar cell panel, the solar cell array further including a wind-blocking wall configured to extend from a portion holding the first edge of the first solar cell panel toward the back surface, and a configured to allow communication between a space on a front surface side of the first solar cell panel and a space on a back surface side of the second solar cell panel through the gap.

### TECHNICAL FIELD

The present invention relates to a solar cell array.

### BACKGROUND ART

In recent years, solar cell arrays have frequently been installed on buildings such as houses so as to use sunlight as electric power.

The solar cell array is configured by electrically connecting and structurally integrating a plurality of solar cell modules (also referred to as solar cell panels in some cases) using a fixing member such as a frame. The solar cell module is configured by electrically connecting a plurality of solar cell elements. Examples of the solar cell element include solar cell elements using a single crystal silicon, polycrystalline silicon, amorphous silicon, CdS and CIS, and a dye-sensitized solar cell element.

Typically, examples of the frame used for a solar cell array include a vertical rack provided along an inclination of a roof and a horizontal rack provided perpendicularly to an inclination of a roof. Currently, the horizontal rack is preferably used from the viewpoints of fewer limitations on installment, and a unified color shade because the inclination and horizontality in a vertical direction of a solar cell panel are maintained.

However, the horizontal rack is disposed so as to cut across a flow path of air (inside air) on a back surface side of the solar cell array, and thus the flow path of air becomes smaller, leading to a decrease in amount of airflow on the back surface side of the solar cell array. As a result, there arises a problem that temperature of the solar cell element increases and the maximum power output Pmax decreases, leading to a decrease in power generation efficiency.

In order to solve the aforementioned problem, as shown in FIG. 8, there is known the method of cooling a solar cell array 100 by providing a through hole 118 penetrating through a horizontal rack 102 in an eaves-to-ridge direction to a side portion thereof so as to increase a size of an air flow path on a back surface side of the solar cell array 100, and thereby increasing an amount of airflow (for example, see Japanese Patent Application Laid-Open No. 2000-101120 and Japanese Patent Application Laid-Open No. 2000-87514).

However, the structure in which a through hole is provided in an eaves-to-ridge direction of a horizontal rack as described above has a problem that a flow amount of air flowing on the back surface side of the solar cell array is small due to a large air resistance when passing through the horizontal rack portion, whereby a sufficient cooling effect cannot be obtained.

Further, in the case of the aforementioned structure, intakes for introducing outside air to the back surface side of the solar cell array are provided only at an edge on an eaves side and an edge on a ridge side of the solar cell array. Accordingly, even if low-temperature outside air is introduced from the edge on the eaves side, air temperature inevitably rises as the air flows toward the ridge side. As a result, there arises a problem that between solar cell panels on the eaves side and the solar cell panels on the ridge side which belong to the same system, unevenness in power generation efficiency resulting from temperature difference therebetween occurs, whereby a sufficient power generation amount cannot be obtained as the entire system despite cooling.

### DISCLOSURE OF INVENTION

The present invention has been made in view of the aforementioned problems, and an object thereof is to provide a solar cell array which has excellent power generation efficiency by efficiently cooling solar cell panels with a simple structure.

According to the present invention, a solar cell array includes a first solar cell panel and a second solar cell panel, and installation member configured to install the first and second solar cell panels, the installation member being disposed with a space on back surface side of the installation member when installed, and holds the first and second solar cell panels with a gap between a first edge along one side of the first solar cell panel and a second edge along one side of the second solar cell panel, the solar cell array further including a wind-blocking wall configured to extend from a portion holding the first edge of the first solar cell panel toward the back surface, and a configured to allow communication between a space on a front surface side of the first solar cell panel and a space on a back surface side of the second solar cell panel through the gap.

In this solar cell array, air (inside air) flowing on the back surface side (for example, inclined surface side) detours the wind-blocking wall, whereby a difference in flow rate generated between the inside air and air (outside air) flowing on a light receiving surface side (front surface side) increases, which leads to the generation of a pressure difference between the inside air and the outside air. This pressure difference becomes pronounced particularly in a case where the solar cell array is installed on the inclined surface. Accordingly, the outside air is efficiently taken into a space on the inclined surface side through the communicating part, and the outside air acts as a heat absorbing medium, which suppresses temperature rise of the solar cell panel.

### BRIEF DESCRIPTION OF DRAWINGS

FIG. 1 is a perspective view showing a solar cell array 20 according to an embodiment of the present invention.

FIG. 2 is a perspective view showing an enlarged vicinity of a dashed-line part D of FIG. 1.

FIG. 3 are enlarged cross-sectional views in a longitudinal direction of a horizontal rack 2 of the solar cell array 20, where FIG. 3(a), FIG. 3(b) and FIG. 3(c) show an A-A′ cross-section of FIG. 1, a B-B′ cross-section of FIG. 1, and a C-C′ cross-section of FIG. 1, respectively.

FIG. 4 is a view describing flow of air in a vicinity of a dashed-line part E shown in FIG. 3(a).

FIG. 5 is a view showing a temperature distribution obtained by a simulation according to Example 1.

FIG. 6 is a figure showing, in solar cell arrays according to Example 2 and Comparative Example, temperature distributions of solar cell panels constituting those.

FIG. 7 are views showing modifications of a part of the solar cell array 20, and in particular, the structure in the vicinity of the dashed-line part E of FIG. 3(a).

FIG. 8 is a cross-sectional view showing an example of a state in which a solar cell panel 101 is fixed with a horizontal rack 102.

### BEST MODE FOR CARRYING OUT THE INVENTION

Hereinafter, a solar cell array according to the present invention is described with reference to the accompanying drawings. Note that in the present invention, the solar cell array is obtained by electrically connecting a plurality of solar cell panels to be structurally integrated. The solar cell panel is obtained by electrically connecting a plurality of solar cell elements, which is also referred to as a solar cell module.

In the present invention, the solar cell elements constituting the solar cell panel are not limited to ones formed of a crystalline semiconductor. Any types may be used as long as they are solar cell elements having such property that power generation efficiency decreases along with a rise in temperature.

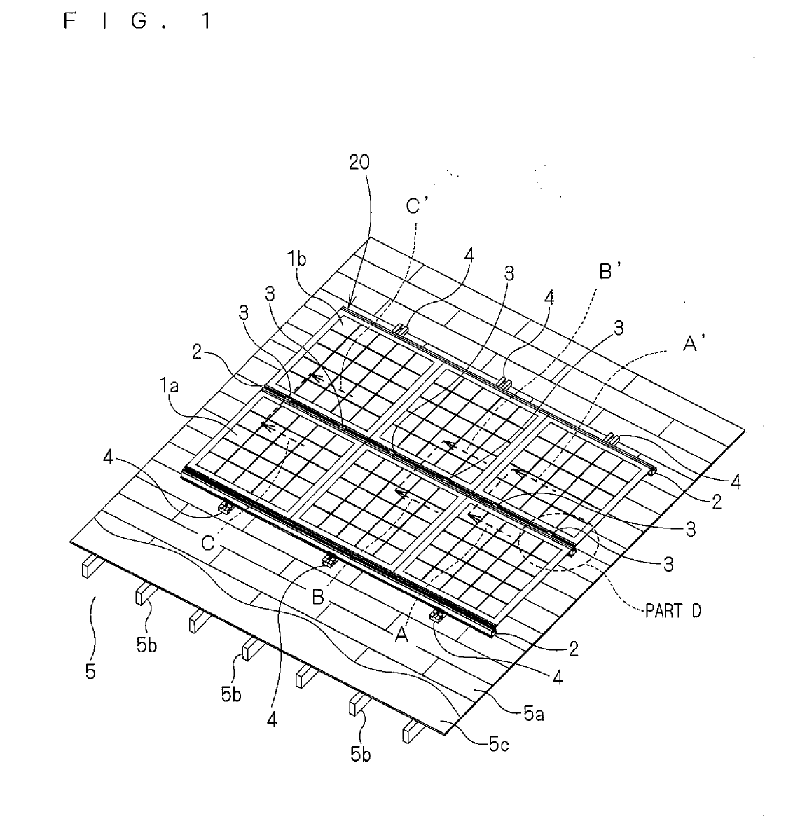

In FIG. 1, the solar cell array 20 according to this embodiment generally has the structure in which a plurality of solar cell panels 1 whose light receiving surface faces upward are disposed two-dimensionally (in a planar manner) on a roof surface 5 which is an inclined surface, using a first installment member (horizontal rack) 2 and second installment members 3. Note that FIG. 1 illustrates a case where two solar cell panels and three solar cell panels are disposed in an eaves-to-ridge direction and in a beam direction of the roof surface 5, respectively, but a mode of arranging the solar cell panels in the solar cell array 20 is not limited thereto. Further, in this embodiment, among the plurality of solar cell panels arranged in the eaves-to-ridge direction of the roof surface 5, ones positioned on a relatively lower side of the adjacent two solar cell panels are referred to as first solar cell panels 1a, whereas ones positioned on a relatively upper side thereof are referred to as second solar cell panels 1b. Hereinafter, the structure of the solar cell array 20 is described in detail.

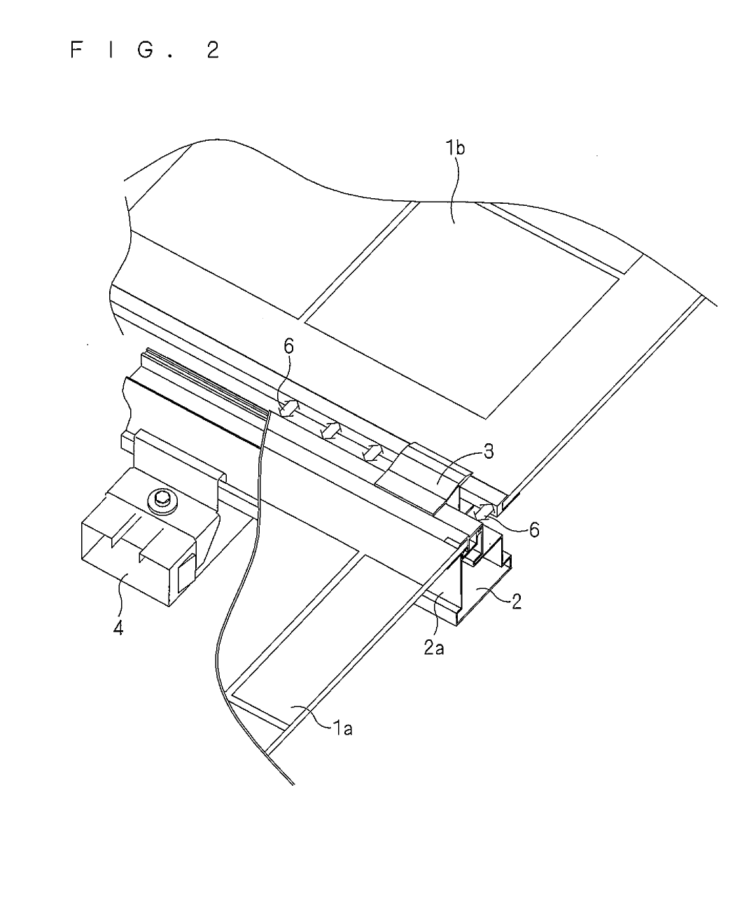

In the solar cell array illustrated in FIG. 1 and FIG. 2, edges on the ridge side of the first solar cell panels 1a are directly held by the horizontal rack 2, and edges on the eaves side of the second solar cell panels 1b are held by the second installment members 3 fixed to the horizontal rack 2. The second installment member 3 is formed of, for example, aluminum.

The horizontal rack 2 is installed such that a longitudinal direction thereof coincides with the beam direction of the roof surface 5. The horizontal rack 2 is installed by being firmly secured to metal fixtures 4 mounted onto the inclined surface of the roof 5 composed of a roof material 5a formed of a slate material, rafters 5b and a sheathing roof board 5c. The horizontal rack 2 is formed of, for example, aluminum. The metal fixture 4 is formed of, for example, SUS or plated steel plate, and is mounted onto the inclined surface of the roof 5 with a screw or the like.

The second installment members 3 are not provided in a continuous manner over an entire length of the horizontal rack 2, but are provided at predetermined intervals in a discrete manner along the longitudinal direction of the horizontal rack 2, as shown in FIG. 1. In addition, as shown in FIG. 2, the horizontal rack 2 and the second installment members 3 hold the edges on the ridge side of the first solar cell panels 1a and the edges on the eaves side of the second solar cell panels 1b so as to have a gap 6 between the horizontal rack 2 and the edges on the eaves side of the second solar cell panels 1b. Note that the horizontal rack 2 and the second installment members 3 are not necessarily required to be provided separately from each other, but may be configured as an integral installment member.

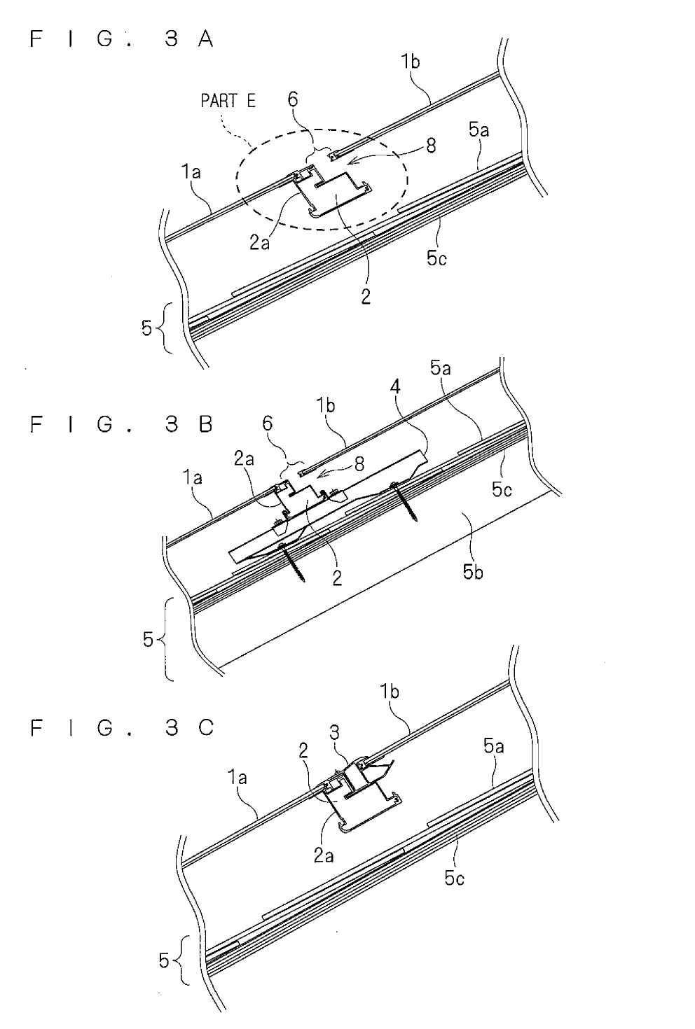

An A-A′ cross-section and a B-B′ cross-section of FIG. 3 are each cross-sections at positions at which the second installment member 3 is not provided. A C-C′ cross-section is a cross-section at a position at which the second installment member 3 is provided.

As shown in FIG. 3(a) and FIG. 3(b), the solar cell array 20 includes, at the position at which the second installment member 3 is not provided, a communicating part 8 through which air can flow in and out between a front surface side (light receiving surface side) and a back surface side via the gap 6. The communicating part 8 is preferably configured so as to allow a space on the front surface side of the solar cell panel and a space on the inclined surface side of the second solar cell panel to communicate with each other.

As shown in FIG. 3(a) and FIG. 3(c), at positions at which the metal fixture 4 is not provided, the solar cell array 20 and the roof material 5a are not brought into contact with each other, and the solar cell panels 1a and 1b and the horizontal rack 2 are positioned with a predetermined distance with the roof material 5a, whereby air can pass below the horizontal rack 2. Note that FIG. 3(c) illustrates a case where the second installment member 3 is provided at a position at which the metal fixture 4 is not provided, but the metal fixture 4 may be provided on the rafter 5b and the second installment member 3 may be provided directly thereabove.

On the other hand, FIG. 3(b) shows the cross-section at a position at which the metal fixture 4 is provided. The metal fixture 4 is disposed at a position on the inclined surface of the roof 5, directly below which the rafter 5b is positioned, and is fixed to the roof 5 with a wood screw which penetrates through the roof material 5a and the sheathing roof board 5c into the rafter 5b.

In addition, as shown in FIG. 2 and FIG. 3, the horizontal rack 2 includes a wind-blocking wall 2a extending toward the inclined surface of the roof 5 over the entire length on a lower part side thereof. As shown in FIG. 3(a) and FIG. 3(c), the wind-blocking wall 2a acts to detour flow of air (inside air) in the vicinity of the back surface side of the solar cell array 20 toward the inclined surface of the roof 5.

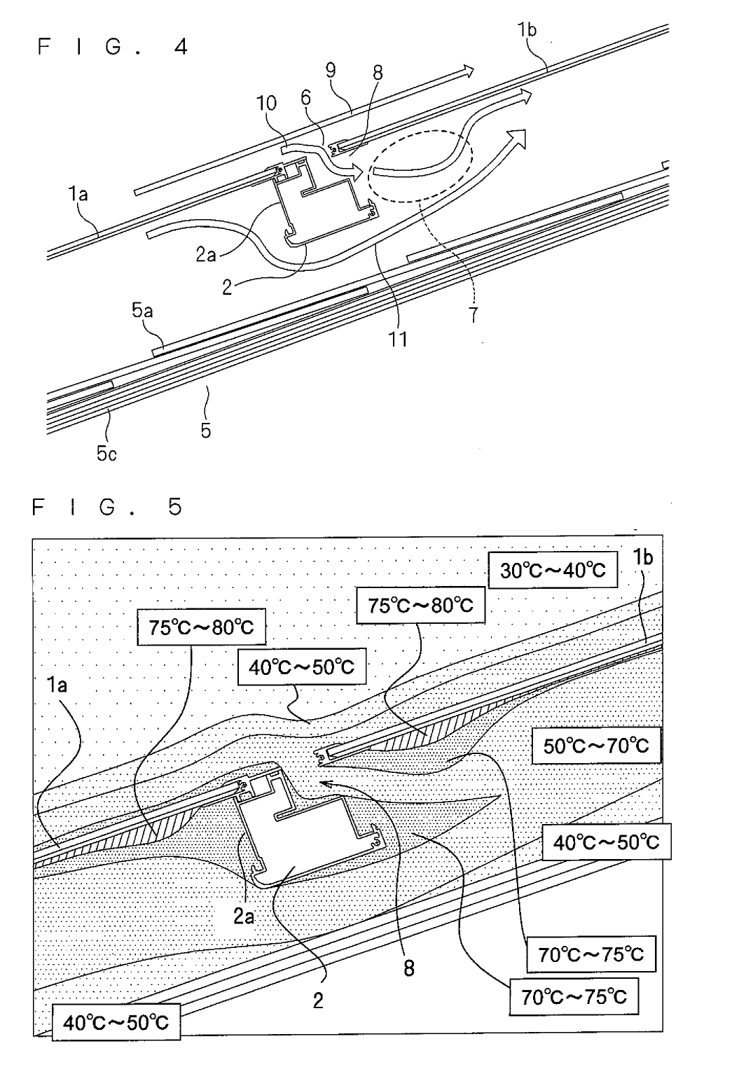

The flow of air in the vicinity of a dashed-line part E shown in FIG. 3(a) is described with reference to FIG. 4. An inside air 11 is introduced into an inclined space between the solar cell panel 1 and the roof 5 from the eaves side by a so-called chimney effect, and travels toward the ridge side. Note that a direction (direction from obliquely lower left toward obliquely upper right in the case of FIG. 4) from the eaves side (back surface side of the first solar cell panel 1a) to the ridge side (back surface side of the second solar cell panel 1b) in the inclined space is referred to as an “uphill direction” below.

However, at a position at which the horizontal rack 2 is provided, the wind-blocking wall 2a extends from the back surface side of the solar cell panel 1 toward the inclined space, and thus the inside air 11 travels around the horizontal rack 2. As a result, on the back surface side of the second solar cell panel 1b, ventilation (flowing) of the inside air 11 toward a space 7 beyond the horizontal rack 2 is suppressed. In addition, a flow path is narrowed due to protruding of the horizontal rack 2, which increases a flow rate of the inside air 11 passing below the horizontal rack 2.

On the other hand, the space 7 also leads to the front surface side of the solar cell panel 1 through the gap 6 and the communicating part 8. A change in flow rate as in the inside air 11 does not occur in an outside air 9 flowing on the front surface side thereof. This results in a state, in the space 7, where a pressure applied from the inside air 11 having a larger flow rate is lower than a pressure applied from the outside air 9 having a smaller flow rate, based on the Bernoulli's principle in fluid dynamics. Because of a pressure difference in this manner, an outside air 10 is taken into the space 7 from the front surface side of the solar cell panel 1 through the communicating part 8.

The inside air 11 is generally heated by convective heat transfer from the solar cell panel 1, as traveling toward the ridge side. In contrast, the outside air 10 is not heated similarly to the inside air 11, and thus has lower temperature compared with the inside air 11. Accordingly, convective heat transfer from the second solar cell panel 1b is promoted when the outside air 10 flows into the space 7 of the inclined space or further into a region in the uphill direction. That is, the outside air 10 acts as a heat absorbing medium, and in particular, effectively suppresses temperature rise of the second solar cell panel 1b in the vicinity of the space 7 serving as an inlet of the outside air 10.

As described above, the solar cell array according to this embodiment is provided with, between adjacent solar cell panels, a communicating part allowing air to flow in and out between the front surface side (light receiving surface side) and the back surface side, and with a horizontal rack including a wind-blocking wall configured so as to allow flow of air (inside air) on the back surface side of the solar cell array to detour. Accordingly, a difference in flow rate between the inside air and the air (outside air) on the light receiving surface side is increased to generate a pressure difference, whereby the outside air is efficiently drawn into the back surface side (in the vicinity of the edge on the eaves side) of the solar cell panel via the communicating part. Because the outside air drawn into acts as a heat absorbing medium, temperature rise of a solar cell panel can be controlled.

As described above, according to this embodiment, it is possible to achieve a horizontal-rack-installed type solar cell array, which is capable of efficiently cooling the solar cell panels with a simple structure, and in which a decrease in power generation efficiency along with temperature rise of the solar cell panels is suppressed.

Note that while the description is mainly given of a case, as an example, where two solar cell panels are arranged in the caves-to-ridge direction, the aforementioned effect of suppressing temperature rise becomes more pronounced in a case where more solar cell panels are arranged in the eaves-to-ridge direction. In the solar cell array according to this embodiment, the outside air is introduced into the back surface side of the all solar cell panels ranging from the eaves side to the ridge side, and therefore a similar effect of suppressing temperature rise is obtained in the all solar cell panels ranging from the eaves side to the ridge side.

### EXAMPLES

### Example 1

In this example, the effect of suppressing temperature rise of the inside air in the solar cell array 20 according to the aforementioned embodiment was checked by a simulation regarding a temperature distribution and air flow using computer aided engineering (CAE). Note that in CAE, COSMOSFloWorks of Dassualt Systemes SolidWorks Corp. was used to perform steady heat conduction analysis.

In this case, simulation conditions of CAE were set such that an outside temperature was 39° C., an angle of an inclined surface was 26.5°, an amount of solar radiation on a vertical surface was 1,000 W/m², and a speed of wind flowing horizontally toward an inclined surface was 0.1 m/s. A length of the solar cell panel 1 in a flow direction (eaves-to-ridge direction) was 1.03 m, a length of the gap part thereof was 10 mm, and a height of the wind-blocking wall thereof was 62 mm.

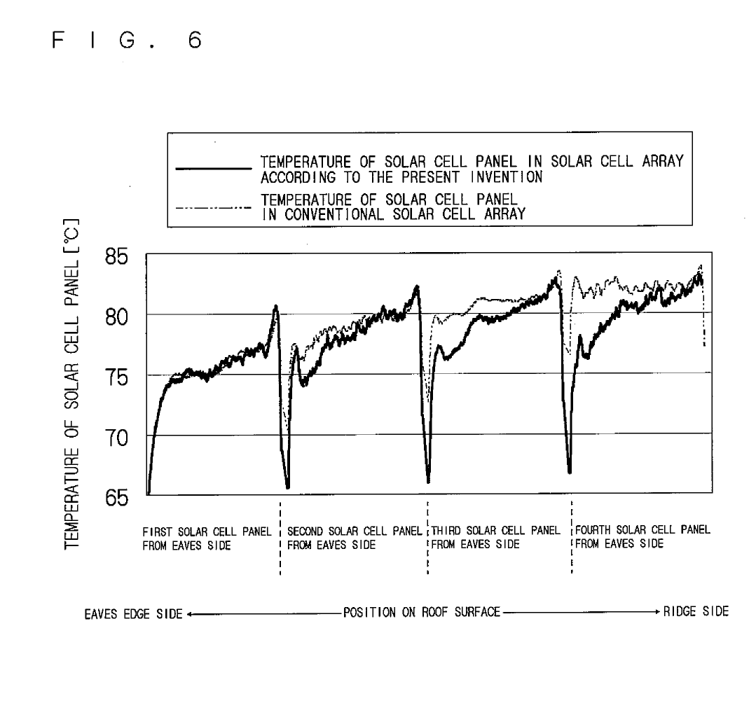

The temperature distribution shown in FIG. 5 reveals that on the light receiving surface side of the solar cell panel 1 (first solar cell panel 1a and second solar cell panel 1b), the air temperature (outside air temperature) in a region at a certain distance away from the light receiving surface ranges from 30° C. to 40° C. It is also revealed that the air temperature rises as the air comes closer to the solar cell panel 1 from the region, and temperature of air present in a contact region with the solar cell panel 1 is 50° C. to 70° C.

On the other hand, on the back surface side of the solar cell panel 1, the temperature of air in a region close to the roof 5 is the lowest, which ranges from 40° C. to 50° C. The air temperature rises as the air comes closer to the solar cell panel 1 from the region, and the temperature of air in a non-contact region with the solar cell panel 1 is 75° C. to 80° C.

It is found, as shown in FIG. 5, that the outside air (50° C. to 70° C.) is introduced into the space on the back surface side of the solar cell panel 1b, and accordingly the region of 75° C. or higher on the back surface side of the solar cell panel 1b decreases toward the uphill direction.

### Example 2

The temperature distribution ranging from the eaves side to the ridge side was measured using the solar cell array in which four solar cell panels 1 are arranged in the eaves-to-ridge direction. Note that as Comparative Example, the temperature distribution of a conventional solar cell array was measured in the same manner. As the conventional solar cell array, one in which a horizontal rack was vertically separated was prepared in place of one having a structure including holes in a horizontal rack as shown in FIG. 8.

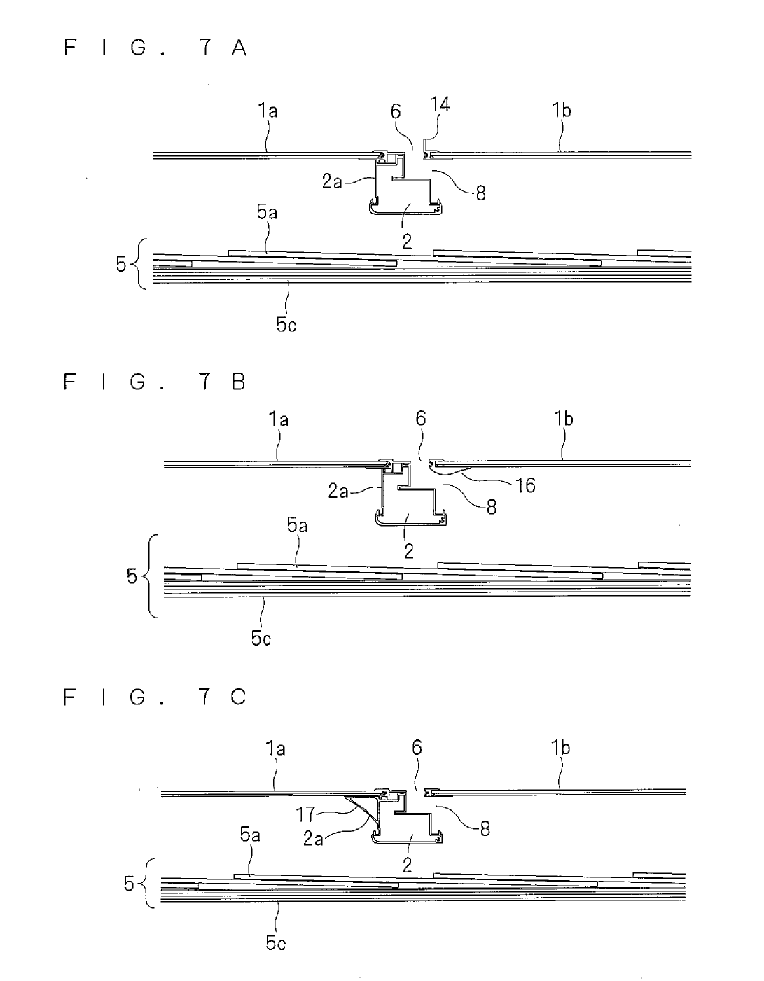

As shown in FIG. 6, in Example 2, there is a tendency that the temperature steeply decreases approximately to 65° C. in an edge on an eaves side and then smoothly rises toward a ridge side in any of the solar cell panels. The tendency of temperature distribution is similar in the respective solar cell panels.

In contrast, it is revealed in the comparative example that a lower limit temperature becomes higher and heat applied to the solar cell panel increases more abruptly as the solar cell panel becomes closer to the ridge side. For example, as to the solar cell panel on the side closest to the ridge (fourth from the eaves side), compared with Comparative Example, a cooling effect for approximately 5° C. was obtained in Example 2.

### (Modifications)

The present invention is not limited to the above-mentioned embodiment, and numerous modifications and variations can be devised without departing from the scope of the invention. For example, even in a case where a roof configured with, for example, a trussed structure of a concrete material or steel is used in place of a roof using a roof material formed of a slate material, the effect of the present invention, such as cooling effect, can be obtained.

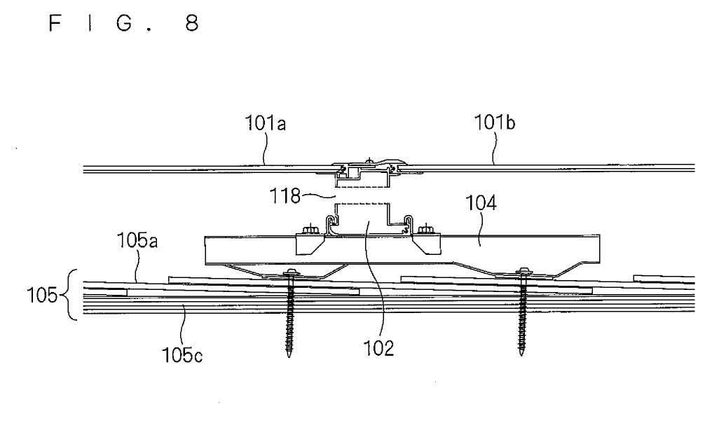

It is possible to devise various modifications in the present invention, for example, as shown in FIG. 7. Hereinafter, those are described as Modification 1 to Modification 3.

### (Modification 1)

This modification is characterized in that, as shown in FIG. 7(a), a guide plate 14 extending toward a space of the light receiving surface side is provided at an edge on the eaves side of a frame part of the second solar cell panel 1b.

By providing this guide plate 14, the air which has flowed through the vicinity of the surface on the light receiving surface side of the first solar cell panel 1a is more easily introduced into the back surface side of the second solar cell panel 1b through the communicating part 8. As a result, an amount of the outside air introduced into the back surface side is increased, and thus heat radiation efficiency can be increased.

### (Modification 2)

This modification is characterized in that, as shown in FIG. 7(b), a wing-shaped frame (bulging part) 16 protruding from the back surface side in a wing shape is used at the edge on the eaves side of the frame part of the solar cell panel 1b.

By providing this wing-shaped frame 16, the air flowing into the back surface side through the communicating part 8 is caused to flow more easily along the back surface of the second solar cell panel 1b, which suppresses the generation of turbulent flow in the vicinity of the communicating part 8. As a result, it is possible to further reduce temperature rise at the edge on the eaves side on the back surface side of the second solar cell panel 1b. Note that the wing-shaped simple frame 16 is configured using light metals such as aluminum and is brought into intimate contact with the second solar cell panel 1b, which further promotes heat radiation from the second solar cell panel 1b.

### (Modification 3)

This modification is characterized in that, as shown in FIG. 7(c), an inclined member 17 is provided in a portion of the wind-blocking wall 2a of the horizontal rack 2.

By providing this inclined member 17, retention of high-temperature air in the vicinity of the wind-blocking wall 2a on the back surface side of the first solar cell panel 1a, as shown in FIG. 5, can be suppressed. In particular, the inclined member 17 is preferably brought into close contact with the first solar cell panel 1a. In such a case, heat radiation from the first solar cell panel 1a is promoted, and hence temperature rise at the edge on the eaves side of the first solar cell panel 1a is suppressed.

1. A solar cell array, comprising:
a first solar cell panel and a second solar cell panel; and
an installation member configured to install the first and second solar cell panels, wherein
the installation member is disposed with a space on back surface side thereof when installed, and holds the first and second solar cell panels with a gap between a first edge along one side of the first solar cell panel and a second edge along one side of the second solar cell panel,
the installation member comprising:
a wind-blocking wall configured to extend from a portion holding the first edge of the first solar cell panel toward the back surface; and
a communicating part configured to allow communication between a space on a front surface side of the first solar cell panel and a space on a back surface side of the second solar cell panel through the gap.

2. A solar cell array, comprising:
a first solar cell panel and a second solar cell panel; and
an installation member configured to install the first and second solar cell panels in order along a direction of an inclination of an inclined surface, wherein
the installation member is disposed to be apart from the inclined surface when installed, and holds the first and second solar cell panels with a gap between a first edge along an upper side of the first solar cell panel and a second edge along a lower side of the second solar cell panel,
the installation member comprising:
a wind-blocking wall configured to extend from a portion holding the first edge of the first solar cell panel toward the inclined surface; and
a communicating part configured to allow communication between a space on a front surface side of the first solar cell panel and a space on a back surface side of the second solar cell panel through the gap.

3. The solar cell array according to claim 1, wherein the installation member comprises:
a first installation member comprising a portion constituting the wind-blocking wall and the portion holding the first edge of the first solar cell panel; and
second installation members comprising the portion holding the second edge of the second solar cell panel.

4. The solar cell array according to claim 3, wherein the first installation member holds approximately an entire region of the first edge of the first solar cell panel.

5. The solar cell array according to claim 4, wherein the second installation members are provided at intervals with each other along the first installation member.

6. The solar cell array according to claim 1, wherein the installation member comprises an inclined part extending from the wind-blocking wall toward a surface on the inclined surface side of the first solar cell panel.

7. The solar cell array according to claim 1, wherein the second solar cell panel comprises a guide member configured to protrude from the second edge toward a space of a front surface side of the second solar cell panel.

8. The solar cell array according to any one of claims 1 to 7 claim 1, wherein the second solar cell panel comprises a bulging part on a back surface of the second edge.

9. The solar cell array according to claim 2, wherein the installation member comprises:
a first installation member comprising a portion constituting the wind-blocking wall and the portion holding the first edge of the first solar cell panel; and
second installation members comprising the portion holding the second edge of the second solar cell panel.

10. The solar cell array according to claim 9, wherein the first installation member holds approximately an entire region of the first edge of the first solar cell panel.

11. The solar cell array according to claim 10, wherein the second installation members are provided at intervals with each other along the first installation member.

12. The solar cell array according to claim 2, wherein the installation member comprises an inclined part extending from the wind-blocking wall toward a back surface of the first solar cell panel.

13. The solar cell array according to claim 2, wherein the second solar cell panel comprises a guide member configured to protrude from the second edge toward a space of a front surface side of the second solar cell panel.

14. The solar cell array according to claim 2, wherein the second solar cell panel comprises a bulging part on a back surface of the second edge.
